(19) United States
(12) Patent Application Publication
(10) Pub. No.: US 2026/0226349 A1
(43) Pub. Date: Aug. 6, 2026

(54) SCINTILLATOR CRYSTAL HAVING CERIUM, CALCIUM, AND MAGNESIUM DOPED LGSO AND ASSOCIATED METHODS

(71) Applicant: CRYSTAL PHOTONICS, INCORPORATED, Sanford, FL (US)

(72) Inventor: Bruce CHAI, Longwood, FL (US)

(21) Appl. No.: 19/043,574

(22) Filed: Feb. 3, 2025

(51) Int. Cl. C09K 11/77; C30B 15/04; C30B 29/34; G01T 1/202

(52) U.S. Cl. CPC C09K 11/77742; C30B 15/04; C30B 29/34; G01T 1/2023

(57) ABSTRACT

A scintillator crystal may include a monocrystalline structure of cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅, wherein x is between 0.0003 to 0.001, y is between 0.0005 to 0.003, and z is between 0.0003 to 0.001. The monocrystalline structure has an R value less than 5 corresponding to the decay time in nanoseconds divided by the light yield with respect to a Bismuth Germanium Oxide (BGO) reference.

### FIELD OF THE INVENTION

The present invention relates to the field of scintillator crystals, and more particularly, this invention relates to cerium doped Lutetium-based scintillator crystals that have increased light yield and reduced decay time and related methods.

### BACKGROUND OF THE INVENTION

Titanite (or Sphene) is a naturally formed mineral having the composition of CaTiSiO₅. This naturally formed crystal is monoclinic in symmetry with a space group of P21/a. Titanite has a unique structure, i.e., it includes two cation sites, i.e., A(7) and B(6), within a three-dimensional (3D) network of silica tetrahedrons, SiO₄. Cation site A(7) is highly distorted with a 7-fold oxygen coordination, but cation site B(6) is much less distorted with a 6-fold oxygen coordination. From the number of oxygen coordination sites, it is evident that the A(7) site is larger than the B(6) site. Although the structure of Titanite is beneficial for many applications, its composition has some technical drawbacks. The Titanite CaTiSiO₅ structure does not melt congruently, and for that reason, it is not possible to produce large, single crystals for applications such as scintillators. For that reason, scintillator crystals are formed from the isomorphs, such as lutetium oxyorthosilicate: LSO (Lu₂SiO₅); yttrium orthosilicate: YSO (Y₂SiO₅); and lutetium-yttrium oxyorthosilicate: LYSO ((Lu,Y)₂SiO₅). These compounds all melt congruently and can be produced in large single crystals as a scintillator host.

In Titanite, the Ca2+ ion is occupied in the A(7) site with a size of 1.07 A, and the Ti4+ ion is occupied in the B(6) site with a size of 0.61 A. Both sites can be substituted by other cations. But the substitution follows four basic selection rules.

First, the dimension of the Titanite structure framework is determined by its 3D SiO₄ network. LSO has a unit cell dimension of a=14.263 A, b=6.643 A, c=10.250 A and β=122.19. YSO has a unit cell dimension of a=14.44 A, b=6.74 A, c=10.42 A and β=122.19. LYSO has a unit cell dimension between the two. Any substituted ion should be comparable in size to the host cations in its respective occupied site. A crystal will reject the substitution if the cation sizes exceed the tolerant limit of the occupied site during growth. At this point, the substitution will be limited.

Second, substitution should satisfy the charge neutrality within the crystal structure. Since Ca2+ and Ti4+ have a combined charge of +6, so are its isomorphs, LSO and YSO, with both Lutetium and Yttrium having a 3+ charge. Any of the substituted cations should also satisfy the total combined charges of +6.

Third, since the substituted Titanite structure compounds of interest have to be produced at very high temperatures, e.g., greater than 2,000° C., the substituting ions should be refractory and survive the high growth temperatures without being evaporated.

Fourth, since the substituted Titanite structure compounds will be used as the host for the light emitting of Ce3+ ions in a scintillator crystal, the other substituted cations should not be light emitters and not interfere with emissions or absorptions of the Ce3+ ions.

Not all elements in the periodic table are suitable for this substitution. Based on the four basic selection rules noted above, there are only a limited number of elements in the periodic table that are suitable for this substitution. Some prior art teachings, for example, U.S. Pat. No. 6,278,832 to Zagumennyi et al. and U.S. Pat. No. 11,319,645 to Wang et al., have listed the majority of elements in the periodic table as possible dopants. This is unjustified. None of the currently known or commercially produced LSO or LYSO crystals contain any of their listed elements. Most of their listed elements cannot survive the high melting temperature, i.e., greater than 2,000° C., during the crystal growth process.

Even if any of these elements survived the high temperature, their small substitution would be considered as contaminants and would not aid crystal performance. In many cases, their substitution may be detrimental and should be avoided. Dopants should be selected based on the selection rules where they can be substituted into the Titanite structure and tolerate the high melting temperatures, i.e., greater than 2,000° C., during growth without being evaporated.

For the larger A(7) cation site, the suitable substituting cations are listed with the ionic diameter for a seven-fold oxygen coordination site shown in parentheses: a) Ca2+ (1.07 A); b) Gd3+ (1.04 A); c) Y3+ (0.96 A); d) Lu3+ (0.91 A); e) Mg2+ (0.80 A); and f) Ce3+ (1.07 A), which is the required light emitting cation.

For the smaller B(6) cation site, the suitable substituting cations are listed with the ionic diameter for a six-fold oxygen coordination site shown in parentheses: a) Ce4+ (0.80 A); b) Sc3+ (0.75 A); c) Lu3+ (0.86 A); d) Y3+ (0.90 A); e) Mg2+ (0.72 A); and f) Ce3+ (1.01 A), which is the required light emitting cation.

The same element occupied in these two different sites may have a different ionic size because the oxygen coordination number is different, and the occupied site size is different. The amount of substitution depends strongly on the ionic size. The three-dimensional SiO₄ lattice network may be distorted when the substituting cation has a different size. However, as a general rule, the lattice network will be more tolerant to the size difference if the substituting cations have a smaller diameter. This tolerance to the size difference is reduced if the substituting cations have a larger diameter. The crystal will reject the substituting ions during growth, and its distribution coefficient will be less than unity. Unfortunately, most of the elements of interest for the substitution have their ionic size larger than the host cations in each respective site. As a result, the amount of doping for each dopant should be carefully selected.

The cation of interest, Ce3+, is considered large for the A(7) site and too large for the B(6) site. For that reason, the substitution of Ce3+ into the Titanite structure is limited with a small distribution coefficient. Based upon prior experience, Ce3+ doping should not exceed more than 0.5% if a reasonable high crystal quality and more uniform Ce distribution are to be retained within the crystal from the top down after growth.

Even though the Titanite structure is suitable as a scintillator host for light emitting cations, the original composition is unsuitable as a crystal scintillator host because it does not melt congruently, and thus, cannot be mass produced. Among the structural Titanite compounds, LSO (Lu₂SiO₅), YSO (Y₂SiO₅), LYSO ((Lu,Y)₂SiO₅), and LGSO (Lu,Gd)₂SiO₅) are the only four known congruent melting isomorphs. The requirement of high density, high gamma-ray stopping power, and ability to be mass produced into high quality, large single scintillator crystals make Ce3+ doped LSO and LYSO a primary gamma-ray detector for time-of-fly positron emission tomography (ToF PET) scanners in medical imaging and other high energy physics applications. For this reason, it is desirable to improve scintillator performance of not only Ce3+ doped LYSO crystals, but also Ce3+ doped LSO and LGSO crystals. Similar improvements on the LYSO crystal should work on these other two isomorphs. Because both LSO and LYSO scintillator crystals are produced commercially and exclusively used in high end ToF PET scanners today, significant improvements in the scintillating performance with new doping composition crystals are desired with cation doping to achieve the highest light yield and fastest decay time for gamma-ray detection.

A scintillator crystal should have sufficient stopping power to capture the incoming high energy gamma-rays. The cations in the scintillator crystal should have a high atomic number and high density. In a list of suitable substituting cations, both Ca2+ and Mg2+ are too light and do not meet that criteria. However, Ca2+ is required as a dopant in the A(7) site because it reduces the Ce3+ decay time in LSO and LYSO crystals. Y3+ also has too low a density and low atomic number of 39, but it is used in some examples as a primary composition for the host crystal because its larger ionic size expands the crystal lattice and permits the larger Ce3+ ion to fit more readily into the A(7) site of the crystal.

Similarly, Mg2+ has drawbacks because it has a low density with its atomic number of 12. For that reason, a charge compensator is desirable to maintain Ce in the 4+ state in the B(6) site. Sc3+ is undesirable because it has a low atomic number of 21 and low density. Even though there is an entire periodic table of elements that may be investigated, the actual usable elements are surprisingly few.

### SUMMARY OF THE INVENTION

A scintillator crystal may comprise a monocrystalline structure of cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅, wherein x is between 0.0003 to 0.001, y is between 0.0005 to 0.003, and z is between 0.0003 to 0.001. The monocrystalline structure has an R value less than 5 corresponding to the decay time in nanoseconds divided by the light yield with respect to a Bismuth Germanium Oxide (BGO) reference.

In an example, x may be about 0.0005. Y may be about 0.0009. Z may be about 0.0005. P may be between 0.01 to 0.99 and r may be between 0.01 and 0.99. P may be about 0.95. R may be about 0.05. The monocrystalline structure may have a scintillating light yield greater than 6.5 BGO and a decay time less than 32 nanoseconds under 511 Kev radiation.

The monocrystalline structure may further comprise at least one additional 2+ charge cation dopant. The at least one 2+ charge cation dopant may comprise one or more of strontium (Sr), zinc (Zn) and cadmium (Cd). The monocrystalline structure may further comprise at least one additional 3+ charge cation dopant. The at least one 3+ charge cation may comprise one or more of Lanthanum (La), Scandium (Sc), Praseodymium (Pr) and Terbium (Tb).

A scintillator crystal may comprise a monocrystalline structure of cerium, calcium and magnesium doped lutetium gadolinium orthosilicate (LGSO) wherein the cerium is about 0.03 at % to about 0.1 at %, the calcium is about 0.05 at % to about 0.3 at %, and the magnesium is about 0.03 at % to about 0.1 at %.

The monocrystalline structure may have an R value less than 5 corresponding to the decay time in nanoseconds divided by the light yield with respect to a Bismuth Germanium Oxide (BGO) reference. The cerium may be about 0.05 at %. The calcium may be about 0.09 at %. The magnesium may be about 0.05 at %. The Lutetium may be about 1 at % to about 99 at %. The Gadolinium may be about 1 at % to about 99 at %. The Lutetium may be about 95 at %. The Gadolinium may be about 5 at %.

A method of making a scintillator crystal from a melt may comprise preparing a melt comprising cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅, wherein x is between 0.0003 to 0.001, y is between 0.0005 to 0.003, and z is between 0.0003 to 0.001. The method includes growing a monocrystalline structure from the melt, the monocrystalline structure having an R value less than 5 corresponding to the decay time in nanoseconds divided by the light yield with respect to a Bismuth Germanium Oxide (BGO) reference.

A scintillator crystal may include a Cerium co-doped with calcium and magnesium in lutetium, gadolinium orthosilicate (LGSO) monocrystal. Calcium will be located in A(7) site of the LYSO crystal structure. It will increase the A(7) site distortion and induce the Ce3+ ions located in A(7) site with higher light emission and faster decay time. Magnesium will be located in B(6) site of the LGSO crystal structure which will eliminate the Ce3+ ions located in the B(6) site by converting them to non-emitting Ce4+ ions via charge compensation. It will completely eliminate the light emission of Ce3+ in B(6) site that has a much slower decay time. This scintillator crystal with the correct doping concentration will have a R value less than 5 which is the ratio of the decay time in nanoseconds divided by the light yield ratio of this monocrystal relative to a Bismuth Germanium Oxide (BGO) crystal reference standard.

### BRIEF DESCRIPTION OF THE DRAWINGS

Other objects, features and advantages of the present invention will become apparent from the Detailed Description of the invention which follows, when considered in light of the accompanying drawings in which:

FIG. 1 is a graph comparing results of prior art LYSO scintillator crystals with Ca only, Mg only, and Ca and Mg co-doped LYSO scintillator crystals.

FIG. 2 is a high-level flowchart of a method of making the LYSO scintillator crystal according to an embodiment.

FIG. 3 is a high-level flowchart of a method of making the LGSO scintillator crystal according to an embodiment.

FIG. 4 is a high-level flowchart of a method of making the LSO scintillator crystal according to an embodiment.

### DETAILED DESCRIPTION

Different embodiments will now be described more fully hereinafter with reference to the accompanying drawings, in which preferred embodiments are shown. Many different forms can be set forth and described embodiments should not be construed as limited to the embodiments set forth herein. Rather, these embodiments are provided so that this disclosure will be thorough and complete, and will fully convey the scope to those skilled in the art.

In accordance with non-limiting examples of the invention, it is possible to simultaneously increase the light yield and reduce the decay time with LSO, LYSO and LGSO scintillator crystals and thus improve the image quality of time-of-flight positron emission tomography (ToF-PET), improve the Coincidence Time Resolution (CTR), and increase the signal-to-noise ratio. This is accomplished by simultaneously co-doping calcium and magnesium with cesium in improved LSO, LYSO and LGSO single scintillator crystals. It has been found possible to achieve a light yield close to 60,000 photons/MeV with a decay time down to 26 ns, and maintain the CTR at minimum. The improved scintillator crystal, in accordance with a non-limiting example, achieves an R value (Decay Time (in ns)/Light Yield (in×BGO)) less than 5.0 as will be explained in greater detail below.

A scintillator crystal may include a Cerium co-doped with calcium and magnesium in Lutetium Orthosilicate (LSO) monocrystal. Calcium will be located in A(7) site of the LSO crystal structure. It will increase the A(7) site distortion and induce the Ce3+ ions located in A(7) site with higher light emission and faster decay time. Magnesium will be located in B(6) site of the LSO crystal structure which will eliminate the Ce3+ ions located in the B(6) site by converting them to non-emitting Ce4+ ions via charge compensation. It will completely eliminate the light emission of Ce3+ in B(6) site that has a much slower decay time. This scintillator crystal with the correct doping concentration will have a R value less than 5 which is the ratio of the decay time in nanoseconds divided by the light yield ratio of this monocrystal relative to a Bismuth Germanium Oxide (BGO) crystal reference standard.

It is known that Titanite is a naturally occurring mineral having a unique crystal structure. Since CaTiSiO₅ does not melt congruently, it is not possible to produce large size single crystals, which limits its application as a host crystal. Fortunately, there are four known Titanite isomorphs that melt congruently, namely: a) YSO (Y₂SiO₅); b) LSO (Lu₂SiO₅); c) LYSO ((Lu,Y)₂SiO₅); and d) LGSO ((Lu,Gd)₂SiO₅). Large, high quality, single crystals from these four compounds can be produced.

YSO was the first titanite isomorph compound discovered. Single crystals of this compound were first produced as a host for Nd3+ doping for laser applications. This crystal had later been doped with Ce3+ for use as a scintillating detector. Even though its scintillating properties are acceptable, this crystal fell short because of its low density, i.e., 4.42 gm/cm³, and low Z number, and thus, had poor stopping power and was unsuitable for high energy gamma-ray detection. For that reason, Ce doped YSO crystals were not investigated in depth when developing the improved scintillator crystals.

To better satisfy the scintillating detector requirement for high energy gamma-rays, LSO doped with Ce3+ was first discovered by Melcher in the late 80's and described in U.S. Pat. No. 4,958,080. This crystal was initially used as a radiation logging detector for oil drilling. The low natural radiation of the Lutetium isotope 176, however, made this application unsuitable. Nevertheless, LSO has a high density of 7.4 gm/cm3, a large Z number of 64, and a high stopping power ideal for high energy gamma-ray detection. The Ce3+: LSO has shown very high scintillating light yield near 30,000 photons/MeV, and has a very fast decay time of 45 ns. This natural low energy radiation of the Lu isotope turns out not to be an issue for PET applications since the scanner requires the detection of two gamma rays in coincidence. As a result, Ce3+: LSO was quickly embraced by the medical establishment in PET scanner detectors. The first commercial LSO PET scanner was introduced by Siemens in 2000.

When initially developed, the charge defects in Ce3+:LSO crystals produced a strong afterglow, which is undesirable for PET applications. Before knowing the true nature of this defect, manufacturers found that doping a small amount of Ca2+ ion effectively reduced the afterglow and maintained a good scintillating light yield.

Spurrier et al. disclosed in 2007 that not only can Ca2+ doping reduce the afterglow, it can also increase the light yield and reduce the decay time at the same time. They reported that with 0.4% Ca2+ co-doping with 0.1% Ce3+, the decay time can be reduced from 46 ns down to 31 ns without much loss of the scintillating light output.

U.S. Pat. No. 7,166,845 to Chai, the disclosure which is hereby incorporated by reference in its entirety, discloses that the defect in LSO, LYSO and LGSO crystals occurred because of oxygen vacancies. These defects were created by losing the weakest non-Si bonding oxygen in the crystal during the high temperature growth under low oxygen ambient condition. Chai '845 discloses it is possible to back fill and repair these oxygen vacancy defects by post growth thermal oxygen annealing. After annealing, the afterglow is greatly reduced and the scintillating light yield of both LSO and LYSO crystals is enhanced without a requirement for Ca2+ co-doping.

Currently, LSO and LYSO are the two best known scintillator crystal materials used as detectors for the high end ToF PET scanners. Even though the post growth thermal oxygen annealing can reduce after glow and greatly increase the scintillating light yield, it cannot reduce the decay time. To further improve the image quality, users of these machines now demand even higher light yields and faster decay times.

The most effective technique reported in the literature was to reduce the decay time by doping the LSO:Ce3+ crystal with Ca2+. LSO crystal co-doped with 0.4% Ca2+ and 0.1% Ce3+ reduced the decay time from 46 ns down to 31 ns. The crystal growth difficulty, however, was increased with higher Ca2+ doping. The developed crystal quality was low and the crystal was easy to fracture, reducing the crystal yield, thus, increasing production cost. Currently, no commercially mass produced LSO or LYSO crystals may be doped with this high a percentage of Ca2+. U.S. Pat. No. 8,062,419 to Andreaco et al. discloses a Ca2+ doping of 0.1 at % and a Ce3+ doping of 0.033 at %. This Ca2+, Ce3+ co-doped LSO crystal has an average light yield of about 40,000 photons/MeV and an average decay time about 33 ns. Atomic percentage (at %) is used throughout the current disclosure unless otherwise specified. The nomenclature used in reference to different papers and patents remain consistent with the original text used by different authors.

In addition to LSO, U.S. Pat. No. 6,624,420 to Chai et. al., the disclosure which is hereby incorporated by reference in its entirety, discloses the production of LYSO single crystals doped with Ce3+ as an alternate scintillating crystal for ToF PET scanner applications. Because both YSO and LSO melt congruently, high quality, large single crystals have been produced from both compositions. The solid solution of LYSO was found to be continuous and extended to the entire composition range from zero to 100% for both Yttrium and Lutetium. YSO, LSO and LYSO were the only known complete congruent solid solution compositions with Titanite structure. LGSO only has a limited solid solution with an LSO end member. The crystal GSO (Gd₂SiO₅) has a different crystal structure because the Gd3+ ion is larger. Because a high crystal density and high Z number are required for scintillation applications, Chai '420 discloses the high Lutetium content LYSO crystal for commercial production.

A current commercial LYSO crystal contains about 10% Yttrium and 90% Lutetium. The LYSO crystal has a slightly lower density of 7.1 gm/cm³ than comparable LSO crystals. The 0.2% Ce3+ doped LYSO has a higher light yield, e.g., near 45,000 photons/MeV, and a decay time about 46 ns after post growth thermal oxygen annealing. The current commercial LYSO crystal has about 0.20% Ce3+ co-doped with 0.05% Ca2+, and a higher light yield of 50,000 photons/MeV, with its decay time reduced to 40 ns.

From a Titanite structural point of view, LYSO should be a better scintillator crystal over both YSO and LSO scintillator crystals because its Titanite structure has two Cation sites, A(7) and B(6) of different size. Because the Y3+ ion is larger than the Lu3+ ion within the Titanite structure, Y3+ will tend to occupy the larger A(7) site, and Lu3+ will remain in the smaller B(6) site. An ideal LYSO crystal should have a composition of 50% Yttrium and 50% Lutetium, and be a perfectly ordered structure where the Y3+ is occupied in A(7) site, and the Lu3+ is occupied in the B(6) site. In practice, this does not occur. The actual crystal structure of LYSO will have both the Y3+ and Lu3+ distributed in both sites, with some preference of the Y3+ into the larger A(7) site, and the Lu3+ distributed into the smaller B(6) site.

In a LYSO crystal with about 10% Yttrium and about 90% Lutetium, it is expected that the majority of the Y3+ will remain in the A(7) site. Larger Y3+ (0.96 A) in the A(7) site will help to substitute more Ce3+ (1.07 A) into the A(7) site. However, even with a much larger size of the 1.07 A in a six-fold coordination, some Ce3+ can still enter into the B(6) site. The total quantity entering the B(6) site, however, will be much smaller.

For LGSO, the situation is different because in both LSO and YSO crystals, the Titanite silicon-oxide 3D structure frame has already been stretched to its limit due to the large host ion size of Yttrium and Lutetium. Gd3+ ion is 1.04 A in a seven-fold oxygen coordination. It is too large and cannot fit into the A(7) site without requiring space yielding from its neighboring B(6) site. Gd3+ cation in a six-fold oxygen coordination also has a size of 0.94 A that is too large, and thus, cannot fit into the B(6) site.

Pure GSO (Gd₂S₁O₅) crustal has a substantially different crystal structure and cannot form a complete solid-solution with either YSO or LSO. Some limited substitution of Gd is possible in the A(7) site in LSO or YSO crystals, but the distribution coefficient is small. Since the Gd3+ is a major host crystal component similar to that of Lu3+, the composition of LGSO crystal is typically not uniform, and the scintillating properties will vary from the top of the crystal down.

Most known commercial manufacturing techniques have focused on doping Ce3+ and Ca2+ ions in both LSO and LYSO crystals without emphasizing Ce4+. Prior teachings have illustrated the detrimental effects of Ce4+ doping due to the supercooling, the poor crystal quality replete with scattering centers, and the yellow coloring that is attributed to the charge defects near the Ce4+ ions.

However, when viewing the Titanite structure, Ce4+ with an ionic size of 0.80 A in a six-fold oxygen coordination should fit into the B(6) site. It is the 4+ charge defect that degrades the scintillating performance. If a 2+ charge cation of the proper ionic size can be found to substitute into the neighboring B(6) site and neutralize the charge, the Ce4+ problem will be eliminated. To satisfy this situation, Mg2+ of 0.72 A in size is an ideal choice.

It has been demonstrated that high quality LYSO crystals with a high light yield and a fast decay time may be produced by simultaneously co-doping Ca2+ coupled with Ce3+ in the A(7) site, and co-doping Mg2+ coupled with Ce4+ in the B(6) site. Prior art techniques, however, have placed the emphasis on the effect of Ca2+ doping with Ce3+. U.S. Pat. No. 6,278,832 to Zagumennyi et al. discloses that Ce3+ can occupy both the A(7) and B(6) sites. Because of the higher distortion of the A(7) site, Ce3+ in the A(7) site will decay much faster, e.g., about 30-38 ns, and the position of the luminescence maximum is centered around 410-418 nm. On the other hand, the distortion of the B(6) site is lower, and as a consequence, the decay of Ce3+ in the B(6) site will be much slower, e.g., about 50-60 ns. The position of the luminescence maximum is also red shifted to 450-500 nm.

The reason for the large variation of the decay time in both LSO and LYSO crystals is because Ce3+ can occupy both sites in variable amounts, depending on the total amount of doping. However, it has been found that it is not possible to isolate the emissions from Ce3+ emission from both sites. Thus, the decay time in both LSO and LYSO crystals is the convoluted average from the emissions of both sites with a single exponential decay formula. Zagumennyi '832 also discloses that there is evidence of an energy transfer from Ce3+ in the A(7) site to Ce3+ in the B(6) site. This decreases the total light output, and increases the decay time to the range of 40-50 ns, and red shifts the peak emission of the luminescence.

It has also been found that it is desirable to maintain the Ce3+ ions in the A(7) site, and eliminate any Ce3+ ions in the B(6) site, which is challenging to accomplish. By understanding the Titanite crystal structure and cation size, it is clear that the LYSO crystal should have a better chance to maintain more Ce3+ in the A(7) site than the LSO crystal. This is because Y3+ ion is slightly larger than the Lu3+ ion and will prefer to occupy the A(7) site during growth, while most Lu3+ ions will stay at the B(6) site.

Given the larger size of the Ce3+ ion, Y3+ ion occupation in the A(7) site will help expand the size of the A(7) site and give Ce3+a better chance to occupy that site. This effect is not 100%, however, since Ce3+ can occupy in both the A(7) site and the B(6) site in a LYSO crystal. Doping the larger size Ce3+ ion into both LSO and LYSO during growth is difficult due to the small distribution coefficient. The majority of the Ce3+ ion will be rejected by the crystal and left in the melt during growth. This will build up excess Ce3+ at the growth interface as the growth progresses. This may cause serious constitutional supercool toward the later stage of the crystal growth.

It has been found that it would be better to maintain most, if not all, the Ce3+ in the A(7) site, and none in the B(6) site, so there will be only one single fast scintillating emission from Ce3+ in the A(7) site. However, this is not entirely possible, and Ce3+ will always migrate into the B(6) site during crystal growth. As a result, it has been determined that it is no longer desirable to eliminate Ce3+ in the B(6) site, but to convert the cerium from the 3+ state into the 4+ state. When this is achieved, the actual amount of cerium in the B(6) site is no longer relevant because the cerium is all in the 4+ charge state and a non-emitter. It will no longer be able to interfere with the scintillating performance of Ce3+ in the A(7) site. To keep cerium in the 4+ state at the B(6) site, the crystal will need a 2+ charge compensator.

It has been determined that Mg2+ is an ideal charge compensator having the correct ionic size to fit well into the B(6) site. Doping Mg2+ into the B(6) site helps maintain the cerium ion in the B(6) site in a 4+ state via pair substitution. When the cerium ion is converted to a 4+ charge, its ionic size is reduced to 0.80 A, making it fit even better into the B(6) site.

Growing LSO and LYSO crystals at a low oxygen ambient in excess of 2000 C will cause the loss of non-silicon bonding oxygen in the A(7) site of the Titanite structure, and create negative charge defects. This may cause serious after glow problems for these crystals. Chai '845 discloses a post growth thermal oxygen annealing process that can back fill the oxygen into these as-grown crystals and repair the missing oxygen defects.

On the other hand, there is no missing oxygen defect in the B(6) site. Co-doping Mg2+ into the B(6) site neutralizes the charge imbalance when converting the cerium ion in the B(6) site from the 3+ to the 4+ state. For the A(7) site, the situation is more complicated. The oxygen vacancy defect in the A(7) site was created during crystal growth due to the loss of the non-silicon bonding oxygen. Ca2+ doping was found to be effective to neutralize the negative charge created by the missing oxygen, and has been used to eliminate the strong after glow problem due to the oxygen vacancy before knowledge had been obtained about the post thermal oxygen annealing process. With Ca2+ ion occupied in the A(7) site, the negative charge is neutralized, but the crystal structure also creates a permanent defect due to the missing oxygen. The missing oxygen defect, however, will not affect the cerium ion, which will remain in 3+ state in the A(7) site. There is a limit on the amount of Calcium doping that may be accomplished, however.

It is not possible to expect that Ca-doping will be able to compensate all the missing oxygen vacancies in the crystals. Too much Ca2+ doping will distort the crystal structure and eventually destroy the crystal. The post growth thermal oxygen annealing disclosed in Chai '845 is the only technique that totally back fills the oxygen vacancies and restores the crystal structure. The oxygen vacancies that have already been neutralized by Ca2+ doping, however, will stay as-is. These missing oxygen sites will create structural distortion within the lattice. It has been determined that this structure distortion can induce the radiative decay of the Ce3+ ion in the A(7) site, and make the decay faster.

In accordance with a non-limiting example, a new technique for pair substitution in LSO, LYSO and LGSO crystals has been developed. Two different types of ion pair substitution have been applied to the host crystals. Ca2+ ions were used to charge neutralization of the missing non-silicon bonding oxygen vacancy in the A(7) site, and Mg2+ ions were used for the charge compensation of Ce4+ in the B(6) site adjacent to each other. In prior art disclosures, on the other hand, Ce4+ was known to be detrimental to the scintillating performance in both LSO and LYSO, but there was no specific solution taught to eliminate it. As disclosed in Zagumennyi '832, there has not been much success. Once the cerium ion was doped into the crystal structure, it cannot be moved.

In accordance with a non-limiting example of the invention, simultaneously two separated pair substitution processes occur, with Ca2+ plus Ce3+ substituting into the A(7) site, and with Mg2+ plus Ce4+ substituting into the B(6) site in LSO, LYSO and LGSO crystals. It is possible to maintain Ce3+ in the A(7) site along with the Ca2+ ion in the A(7) site. It is also possible to convert all the cerium ion in the B(6) site into the 4+ charge with the help of Mg2+ co-doping as a charge compensator. Ce3+ in the A(7) site will be the only scintillating light emitter, while Ce4+ in B(6) site is a non-emitter. It is possible to maintain Ce3+ occupying only the A(7) site, and practically none in the B(6) site when co-doped with Ca2+ and Mg2+. Ce4+ and Mg2+ pair substitution has been found to be an advantageous charge compensation situation. When there is no Mg2+ doping, there is evidence that Ca2+ in the A(7) site can also act as charge compensator for Ce4+ in the B(6) site if the Ca2+ ion occurs in the neighboring site. This kind of charge neutralization will also work, but is not as effective.

Some prior art proposals concentrated on the site occupation of the Ce3+ ions, while neglecting the site occupation of the Ce4+ ions. From a structural point of view, Ce3+ can be substituted into both the A(7) and B(6) sites. Since the A(7) site is the larger of the two, it will be the preferred site for Ce3+ ion. Yamaga et al., “Persistent Phosphorescence in Ce-Doped Lu₂SiO₅,” Optical Material Express, Vol. 2, p. 413 (2012), showed that the ESR measurement result indicated that 95% of the Ce3+ ions occupy the A(7) site and only 5% occupy the B(6) site without Ca2+ co-doping. Since Ce3+ in the A(7) site has a slightly higher energy level over B(6) site, there is also evidence that some of the excited energy of Ce3+ in the A(7) site can be transferred to Ce3+ in the B(6) site and reemit if they are close to each other.

Since the A(7) site is a more distorted site, the emission will have a faster decay in the mid-30 ns range. The B(6) site is much less distorted, so the emission decay is much slower in the mid-50 ns range. Since the total quantity of Ce3+ occupied in the B(6) site is small, not all the Ce3+ in the A(7) site will have the chance to closely neighbor the Ce3+ in the B(6) site.

As a result, only a small fraction of the Ce3+ in the A(7) site will be able to transfer some of its energy to Ce3+ in the B(6) site and reemit. The majority of the Ce3+ in the A(7) site will still emit the light directly without the transfer. As a result, the measured light yield and decay time will be the combined emissions from both sites. The decay constant of the Cerium doped LSO crystal will typically have an average decay time from these two sites in the mid-40 ns.

In the case of Cerium doping in a YSO crystal, the situation is slightly different. Since Y3+ (0.90 A) is larger in six-fold oxygen coordination than Lu3+ (0.86 A), and also occupies 100% of the B(6) site, it will expand the site volume of the B(6) site making the substitution of the Ce3+ (1.01 A) into the B(6) site slightly easier. As a result, more Ce3+ ion can occupy the B(6) site in a YSO crystal. This will significantly increase the chance of energy transfer from Ce3+ in the A(7) site to Ce3+ in the B(6) site. As result, a significant larger portion of the emission will emit from Ce3+ in the B(6) site. The measured long 60 ns decay time of the Ce3+ emission in the YSO crystal clearly reflects this fact.

It is also known from prior teachings that Ca2+ co-doping in LSO and LYSO can decrease the decay time of the Ce3+ emission. A good example is Example 3 in the disclosure of the '419 Patent to Andreaco. A LSO crystal was grown doped with 0.1% of Ca2+ and 0.033% Ce3+. The crystal showed high light yield (5.13×BGO) and a decay time of 33 ns. The decay time was reduced from the normal 45 ns down to 33 ns with Ca2+ co-doping. The 33 ns decay time was consistent with the Yamaga et al. report from Optical Material Express (2012) as noted above that virtually all the emission was coming from Ce3+ in the A(7) site and none from the B(6) site. The result did not indicate that all the cerium ion was occupied only in the A(7) site. Some cerium ions probably were still occupied in the B(6) site. These cerium ions in the B(6) site must have fully converted from the 3+ state to the 4+ state by the nearby Ca2+ ions in the A(7) site after the thermal oxygen annealing. These Ce4+ ions were overlooked because they did not emit any light. Comparing the large size difference of Lu3+ ion of 0.91 A in the A(7) site and the Ce3+ of 1.07 A in the same A(7) site, it is fully expected that the substitution of Ce3+ into the LSO crystal will be even more difficult with a smaller distribution coefficient.

Andreaco '419 disclosed in Example 4 a LSO crystal of 0.1% magnesium co-doped with 0.025% cerium. The crystal had a light yield of 6.27×BGO or 22% higher than that in Example 3 with Ca2+ co-doping. But its decay time was also much longer at 36 ns. In the Andreaco '419 Example 5 of a LSO crystal doped with 0.1% Sr2+ and 0.025% cerium, it had a light yield of 6.04×BGO, which was also 18% higher than that of Ca2+ co-doping. The decay time was about 36 ns. The Andreaco '419 patent also showed in Example 10 a LSO crystal doped with 0.2% cerium and also 0.01% calcium plus 0.015% magnesium. This crystal had a light yield of 5.86×BGO, but the decay time had increased to 47.7 ns because there were not enough calcium plus magnesium to charge compensate the cerium ion. Essentially all the cerium ions occupied in the B(6) site in the 3+ state.

It is desirable to increase the light yield and reduce the decay time of the Ce3+ scintillating emission in the LSO, LYSO and LGSO crystals simultaneously, so that the Coincidence Time Resolution (CTR) can be reduced. Prior art examples demonstrated the reduction of the decay time down to mid-30 ns with calcium co-doping. In the past, this result was acceptable, but currently it is no longer enough because the PET industry is seeking even better scintillator materials that can provide even higher light yields and faster decay times, and thus, a much reduced CTR. The overall ToF PET performance is determined by the CTR, which is proportional to the square root of decay time divided by the light yield.

For that reason, the current examples explained below aim for the best combination of calcium, magnesium, and cerium co-doping in LSO, LYSO and LGSO crystals to increase the scintillating light yield and reduce the decay time. This occurs by optimizing the co-doping concentrations of Ca2+ in the A(7) site and Mg2+ in the B(6) site simultaneously. Increasing the calcium doping can increase the distortion of the SiO₄ 3D structure frame by keeping the structure defect of the missing oxygen. This defect can affect the transition probability of the neighboring Ce3+ in the A(7) site, and thus, induce faster decay. The influence of Ca2+ can only be effective if it is in close neighborhood of the Ce3+ ion. More Ca2+ doping will increase the chance to have more in close neighbor to the Ce3+ ion. But there is also a limit of the total amount of Ca2+ ion doping because Ca2+ doping does not repair the missing oxygen defects, but keeps them in place. The crystal lattice is distorted as a result. There is a limit on how much the total amount of calcium can be doped without destroying the lattice structure of the crystal.

The Ce3+ light emission is unique among the rare earth elements. Typical rare earth element emissions are f-f inner transitions independent of the outer environment of the substituting site. But, the Ce3+ emission is not a f-f inner transition, but a 5d-4f transition with a broad vibronic energy band. As a result, the d-shell electrons will be strongly affected by the outer crystal field strength of the substituting site. The site symmetry, the oxygen coordination number, and the crystal field strength have a profound influence to the emission wavelength, emission strength (i.e., light yield) and the transition probability (i.e., decay constant). There now follows three examples of Ce3+ doped crystals that illustrate this effect.

I. Ce3+ doped YAG (Y₃Al₅O₁₂— Yttrium Aluminum Garnet). YAG is cubic in structure with Y3+ ion occupied in the dodecahedral site with an eight-fold coordination of the oxygen. This dodecahedron site is large and highly symmetrical, but also relatively weak in crystal field strength. As a result, Ce3+ in YAG showed very strong yellow emission centered at 525 nm with a decay constant of 94 ns. The large red-shift of the Ce3+ emission, and the slow decay time relative to LSO and LYSO, are due to the high site symmetry and weak crystal field strength of the Ce3+ substituting site in YAG.

II. Ce3+ doped GSO (Gd₂SiO₅— Gadolinium orthosilicate). GSO is monoclinic in symmetry with the Gd3+ ions occupied in two distinct sites, i.e., a) a larger site with 9-fold oxygen coordination, A(9), and b) a smaller site with 7-fold oxygen coordination, B(7). Both Gd3+ sites in GSO have low symmetry and are highly distorted with the B(7) site, however, more distortion than the A(9) site. Because of the large Ce3+ ionic size, most of the Ce3+ ion will occupy the larger A(9) site, and only a very small fraction of the Ce3+ ion will occupy the smaller B(7) site. As a result, there are also two emissions of Ce3+ in GSO crystals, peaked at 423 nm and 452 nm, respectively.

The emission wavelengths are similar to that of LSO and LYSO crystals without a red-shift. There is also some energy transfer from the A(9) site to the B(7) site. Most emissions, however, will still come from the A(9) site since the overwhelming majority of the Ce3+ ions are occupied in that site. The decay time of 68 ns is dominated by the lower energy A(9) site. Longer decay time is due to the weaker crystal field strength of the larger crystal site. The light yield of GSO is only 2.5×BGO, thus weaker than that of LSO and LYSO because of the weaker crystal field strength.

III. Ce3+ doped LSO (Lu₂SiO₅— Lutetium orthosilicate). LSO is monoclinic in symmetry with the Lu3+ ions in two distinct sites, i.e., a) a larger site with seven-fold oxygen coordination A(7), and b) a smaller site with six-fold oxygen coordination, B(6). In LSO, the A(7) site has low symmetry and is a highly distorted site, while the B(6) site is more symmetric. The Zagumennyi '832 patent discloses that Ce3+ ion occupies both the A(7) and the B(6) site. Because of the higher distortion of the A(7) site, Ce3+ decay of emission is much faster at around 30-38 ns, and the position of the luminescence maximum is centered around 410-418 nm.

On the other hand, the distortion of the B(6) site is much less. As a result, the decay of the Ce3+ emission is much slower at about 50-60 ns. The center of the luminescence maximum is also red shifted to about 450-500 nm. Zagumennyi '832 also discloses that most, e.g., 95%, of the Ce3+ ions are occupied in the larger A(7) site, while only a smaller fraction, e.g., 5%, of the Ce3+ ions are occupied in the smaller B(6) site.

From these three examples, it is evident that to achieve fast decay of the Ce3+ ion, it is necessary to obtain a crystal host structure that is highly distorted, has low symmetry, and smaller cation sites. The A(7) site in LSO, LYSO and LGSO crystals appears to be the best, even better than the B(7) site in GSO crystal because of the smaller size. The presence of the higher symmetry B(6) site in these crystals is undesirable since it still can be occupied by the Ce3+ ions. It should be understood that these Ce3+ ions in the B(6) site can take the energy away from the Ce3+ ions in the A(7) site, and emit light with longer wave length and produce a slower decay time.

In accordance with non-limiting examples, two “pair substitution” of Ca2+ plus Ce3+ in the A(7) site and Mg2+ plus Ce4+ in the B(6) site is achieved. Since Ce4+ ion is much smaller and can fit well in the B(6) site, it will be charge neutralized by the Mg2+ ion in the neighboring B(6) site. Even though Mg2+ with the size of 0.72 A can fit well into the B(6) site by itself, doping is not always straightforward nor automatic, since Mg2+ doping by itself will create a positive charge defect in the B(6) site that is not desirable. Mg2+ doping should be coupled with Ce4+ doping to achieve charge neutralization.

When Mg2+ is doped alone with Ce3+, without Ca2+ co-doping, it will be attracted by the negative charge defect of the missing oxygen and occupied in the A(7) site, and lose the charge compensating power to the Ce4+ ion. To obtain the Ce3+ emission in the A(7) site below the intrinsic 33 ns, it is necessary to dope both Ca2+ and Mg2+ in the right amount.

To demonstrate the effect of simultaneous pair substitutions of calcium plus cerium doping in the A(7) site, and magnesium plus cerium doping in B(6) site on the scintillating properties of LYSO, LSO and LGSO crystals, specific growth experiments were designed and performed. Once the initial calcium, magnesium, and cerium doping concentrations were selected, it was possible to grow a full production size single crystal. Doping so many elements at the same time is a complex task because the dopants have different distribution coefficients during the crystal growth.

The doping concentration can vary from the top of a crystal down. It is not possible to determine quality and production issues until a full production size crystal is grown and then evaluated. It will be necessary to check the crystal quality after each growth. The scintillating light yields are measured and recorded. In addition, the rise and decay times of the scintillating light are also measured and recorded.

As noted before, the overall performance of the ToF PET is determined by the Coincidence Time Resolution (CTR), which is proportional to the square root of the decay time divided by the light yield of the scintillating crystal. To obtain the shortest CTR, it is necessary to achieve both high light yield and faster decay. To decrease the CTR is a primary goal in the manufacturer of scintillator crystals for ToF PET scanners.

In order to make easy comparison of the scintillating performance among the different detector crystals, a new parameter is introduced, i.e., the R value, which is the ratio of the decay time in nanoseconds (ns) divided by the light yield, which is expressed as the number of times to that of a BGO (Bismuth Germinate Bi₄Ge₃SiO₁₂) reference standard. For the R value calculation, BGO has a light yield of 7800 Photons/MeV. If there is a reported light yield in Photons/MeV, it is divided by the number by 7800 to obtain the ratio to BGO.

Using this technique, it was determined that the currently mass produced calcium and cerium co-doped LYSO crystals with a 40,000 photons/MeV light yield and a 40 ns decay time have an R value of 6.38. The calcium and cerium co-doped LSO crystal illustrated in the '419 Andreaco's Example 3 has a R value of 6.40, essentially the same as the currently commercially produced LYSO crystal. The magnesium, cerium, co-doped LSO, i.e., Example 4 of Andreaco '419, has an R value of 5.66, which was the best value among all the examples in that disclosure, despite that the decay time was long at 35.5 ns. These examples show that in order to obtain the lowest R value, it is necessary to have both high scintillating light yield and short decay time. This is a clear demonstration that faster decay is not the only parameter to be pursued. Higher light yield is just as important. The calcium, magnesium, cerium co-doped LSO, i.e., Example 10 in Andreaco '419, only has R value of 8.14. The R value for all 10 examples listed in the Andreaco '419 patent are calculated and summarized below.

### Examples from U.S. Pat. No. 8,062,419

| | |
|---|---|
| Example 1 | LSO, 0.05% Ca + 0.10% Ce --> No data |
| Example 2 | LSO, 0.10% Ca + 0.025% Ce --> No data |
| Example 3 | LSO, 0.10% Ca + 0.033% Ce --> DT = 33 ns, |
| | LY = 5.16, R = 6.40 |
| Example 4 | LSO, 0.10% Mg + 0.025% Ce --> DT = 35.5 ns, |
| | LY = 6.274, R = 5.70 |
| Example 5 | LSO, 0.10% Sr + 0.025% Ce --> DT = 35.8 ns, |
| | LY = 6.04, R = 5.93 |
| Example 6 | LSO, 0.05% Ca + 0.10% Ce --> DT = 38.2 ns, |
| | LY = 5.35, R = 7.14 |
| Example 7 | LSO, 0.01% Mg + 0.35% Ce --> DT = 47.36 ns, |
| | LY = 6.246, R = 7.58 |
| Example 8 | LSO, 0.02% Sr + 0.20% Ce --> DT = 47.8 ns, |
| | LY = 5.456, R = 8.76 |
| Example 9 | LSO, 0.05% Zn + 0.20% Ce --> DT = 46.65 ns, |
| | LY = 6.01, R = 7.76 |
| Example 10 | LSO, 0.01% Ca + 0.015% Mg + 0.2% Ce --> |
| | DT = 47.7 ns, LY = 5.86, R = 8.14 |
| Example 11 | LYSO, 0.15% Ca + 0.10% Ce --> DT = 36.34 ns, |
| | LY = 4.32, R = 8.41 5% Y |
| Example 12 | LYSO, 0.01% Ca + 0.015% Mg + 0.2% Ce --> DT = |
| | 45.64 ns, LY = 5.26, R = 8.68 1% Y |

It is evident that the best crystal in these examples is Example 4 for the LSO with Magnesium doping. It has a R value of about 5.70. Essentially, the other crystals in the other examples have an R value more than 6, indicative of how difficult it is to achieve an R value below 5.0. That R value 5.0 is used as a threshold and it is challenging to achieve this value. To obtain an R value below 5.0, there is little room to modify the doping concentrations. The calcium, cerium co-doped LSO detector in accordance with the '419 patent achieves 200 picoseconds (ps) CTR and has an R value of 6.40. To achieve 160 ps CTR, it is necessary to choose a detector material having an R value of about 4.20, which is a very difficult value to achieve.

Based on the data collected by the current inventor on LYSO crystals, it was determined that if a crystal has an R value of 5.0 and below, it will be an excellent scintillating material. This R value can be used for any scintillator materials for direct comparison. For example, among all current known scintillator materials, Ce-doped LaBr₃ with a light yield of 7.7×BGO (60,000 photons/MeV) and 27 ns decay time is the best with the lowest R value of 3.5. Unfortunately, LaBr₃ has many other undesirable properties, making it unsuitable for ToF PET application, even with that lower R value.

In different embodiments, better combinations of dopant concentrations for the cerium, magnesium and calcium in LYSO, LSO and LGSO crystals have been determined to achieve the lowest R value, i.e., below 5.0. Examples based on specific experiments are now explained.

A. Example 1. To test the idea of Ca2+ and Ce4+ pair substitution in a LYSO crystal, a first growth experiment was conducted with 0.09% of calcium and 0.05% of cerium. The standard Czochralski melt was used as the pulling technique to grow the crystal. A large full size, perfect single crystal of LYSO was produced. The crystal was cut into slices for evaluation. The light yield and decay time of the first and last slice of the crystal after the thermal oxygen annealing process were reported. Knowing the performance of these two slices, it became possible to know the performance of the entire crystal boule. The following were measured values.

The bottom slice of the annealed crystal had a light yield of 6.59×BGO reference, and a decay time of 32.47 ns, with an R value of 4.93. The top slice of the annealed sample had a light yield of 7.32×BGO reference, and a decay time of 34.63 ns, with an R value of 4.73.

For comparison, Example 3 of Andreaco '419 disclosed a good LSO crystal with 0.033% cerium and 0.1% calcium that showed an average light yield of 5.13×BGO reference and an average decay time of 33 ns with an R value of 6.40.

B. Example 2. In this example, the effect of magnesium co-doped with cerium was tested in a LYSO crystal without the calcium doping. The crystal was doped with 0.085% magnesium and 0.05% cerium. Again, the standard Czochralski melt pulling technique was employed to grow the crystal similar as in Example 1. A full size perfect single crystal of LYSO was produced, which was then cut into slices for evaluation. The light yield and decay time of the first and last slice of the crystal after the thermal oxygen annealing were measured. The following were measured values.

The bottom slice of the annealed crystal had a light yield of 7.59×BGO reference, and a decay time of 36.68 ns, with an R value of 4.83. The top slice of the fully annealed sample had a light yield of 7.64×BGO reference, and a decay time of 37.16 ns, with an R value of 4.86.

This is the highest known light yield that was achieved for a LYSO crystal. Since the BGO crystal reference has a light yield of 7800 Ph/MeV, this translated to the actual light yield closer to 60,000 Photons/MeV for the magnesium and cerium co-doped LYSO, comparable to that of Ce:LaBr₃.

The decay time constant of this crystal was much longer, indicating that many Ce3+ in the B(6) site were emitting. These emissions occur because without the Ca2+ co-doping, the attraction of the negative charge created by the missing oxygen in the A(7) site was strong. Mg2+ was attracted by the negative charge created by the missing oxygen in the A(7) site and neutralized. It lost its ability as a charge neutralizer for the cerium ion in the B(6) site. As a result, cerium ion in the B(6) site was stayed in 3+ state, even after the thermal oxygen annealing, because of the lack of the 2+ charge compensator. It was possible to obtain the higher light yield, but the decay time was too slow. As the result, even with the higher light yield, the R value was only just below 5, comparable to that of the calcium, cerium co-doped crystal, and no better.

For comparison, Andreaco '419 in Example 4 tried to co-dope 0.1% magnesium with 0.025% cerium in LSO. The result showed excellent light yield of 6.2×BGO, with a decay time of 35.5 ns, and an R value of 5.66.

C. Example 3. The first two examples showed the effect of pair substitution of either calcium with cerium or magnesium with cerium in LYSO crystals alone. Both examples showed the positive effect of co-doping, but in different ways. They both also showed shortcomings.

In this third example, 0.05% magnesium and 0.09% calcium were co-doped with 0.05% cerium in the LYSO crystal. Again, the same standard Czochralski melt pulling technique was employed to grow the crystal the same as in Example 1. It was possible to produce a full size perfect single crystal of LYSO. The crystal was then cut into slices for evaluation. The light yield and decay time of the first and last slice cut out of the crystal after the thermal annealing process were measured. The following were the measured values.

The bottom slice of the annealed crystal had a light yield of 6.75×BGO reference, and a decay time of 30.60 ns, with an R value of 4.53. The top slice of the annealed sample had a light yield of 7.39×BGO reference, and a decay time of 31.83 ns, with an R value to 4.31.

These results were advantageous because this was the lowest R value achieved on LYSO crystals. The light yield of this crystal was comparable to that of Example 1 and Example 2, but the decay time was distinctly shorter. This is the first time it was possible to reach the 30 ns decay time and still be able to maintain very high light yield.

D. Example 4. Knowing the excellent scintillation performance result of calcium, magnesium co-doped LYSO crystal in Example 3, it was possible to explore the effect with higher co-doping. In this example, the magnesium doping was increased slightly to 0.07%, along with the same 0.09% calcium doping, and 0.05% cerium doping in the LYSO crystal. The same standard Czochralski melt pulling technique was employed to grow the crystal the same as in Example 1. A full size perfect single crystal of LYSO was produced. The crystal was then cut into slices for evaluation. The light yield and decay time of the first and last slice cut out of the crystal after the thermal oxygen annealing process was reported. The following were the measured values.

The bottom slice of the annealed crystal had a light yield of 6.84×BGO reference, and a decay time of 33.08 ns, with an R value of 4.84. The top slice of the annealed sample had a light yield of 7.30×BGO reference, and a decay time 33.27 ns, with an R value of 4.56.

These results show that it was possible to retain the same higher light yield as in Example 3, but the decay time was back to the 33 ns range, the same as Example 1. This example illustrates that higher doping allows smaller Mg2+ ion to migrate into the A(7) site. Its smaller size effectively cancelled the lattice distortion effect created by the larger Ca2+ ion. As a result, the overall structural distortion was less, and the effect on Ce3+ emission in the A(7) site was also reduced, and the decay constant slowed down. The amount of magnesium doping difference between Example 3 and Example 4 was very small, i.e., only about 0.02%, but the actual effect on the scintillating performance of the LYSO crystal was significant.

E. Example 5. Knowing the high sensitivity and the limitation of the higher Mg2+ doping concentration, it was decided to explore the effect of the higher Ca2+ doping. A new growth run was started with 0.15% calcium doping along with 0.05% magnesium and 0.05% cerium in LYSO crystal. The same standard Czochralski melt pulling technique was employed to grow this crystal the same as in Example 1. It was possible to produce a full size perfect single crystal of LYSO. The crystal was then cut into slices for evaluation. The light yield and decay time of the first and last slice cut out of the crystal after the thermal oxygen annealing process was measured. The following were the measured values.

The bottom slice of the annealed crystal had a light yield of 6.39×BGO reference, and a decay time of 31.37 ns, with an R value of 4.91. The top slice of the annealed sample had a light yield of 6.85×BGO reference, and a decay time of 31.13 ns, with an R value of 4.54.

Comparing to both Example 3 and Example 4, magnesium doping performed well to eliminate most to all of the Ce3+ in the B(6) site. Increasing the Ca2+ doping in the A(7) site did not change much the decay time, but it showed the reduction of light yield of Ce3+ in the A(7) site. As result, the R value increased, but only slightly. This result illustrates that the negative effect of higher Ca2+ doping concentration is not as sensitive as that of higher Mg2+ doping.

F. Example 6. The result of Example 5 showed that the negative effect of higher Ca2+ doping was not as sensitive as compared to that of higher Mg2+ doping. A new growth run was started with much higher Ca2+ co-doping of 0.50%, along with 0.05% Mg2+, and 0.05% Ce3+ in a LYSO crystal. Again, the same standard Czochralski melt pulling technique was used to grow the crystal the same way as in the Example 1.

Higher calcium doping caused the crystal to be more stressed and the crystal was fractured after growth. However, it was possible to still harvest some crystal sample pieces for the evaluation. A large portion of the crystal was unusable because of the fracture. Increasing Ca2+ doping will increase the risk of crystal fracture after growth, reduce the crystal yield, and greatly increase the crystal cost. The following were the measured values.

The bottom slice of the annealed crystal had a light yield of 5.29×BGO reference, and a decay time of 26.59 ns, with an R value of 5.03. The top slice of the annealed sample had a light yield of 5.98×BGO reference, and a decay time was 28.69 ns, with an R value of 4.80.

The result showed that higher calcium co-doping can further reduce the Ce3+ decay time down to 27 ns, comparable to that of the Ce:LaBr₃. On the other hand, the quantum efficiency of scintillating emission was reduced at the same time, and the light yield was also noticeably decreased. As a result, the R value did not decrease further, but actually increased slightly. Since CTR is proportional to the square root of the ratio of decay time over light yield or the square root of R value, further increasing the calcium doping will only continue to increase R value and not improve the CTR.

Higher calcium doping with magnesium in cerium doped LYSO crystal will not further reduce the R value, but will still be about 5.0. This indicates that the higher calcium doping LYSO crystal is still an excellent scintillator material. The sensitivity of higher calcium doping is much less and it is possible to tolerate much larger Ca2+ doping concentration, varying from 0.05% up to 0.50%, as long as it is co-doped with magnesium. The loss of scintillating light yield is noticeable and will continue to decrease with even higher calcium doping. It can be used with PET detectors with excellent performance. The actual choice of the doping composition of the LYSO crystal will depend entirely on the design and the requirement of the ToF PET scanner. The higher risk of crystal fracture with higher Ca2+ should not be ignored when selecting a doping concentration.

G. Example 7. The pair substitution studies have been conducted so far using LYSO as host crystal. It was possible to do the same studies on LSO crystal, starting with a new growth of LSO crystal with the same co-doping concentration as Example 3, namely, 0.05% magnesium and 0.09% calcium with 0.05% cerium. Again, the same standard Czochralski melt pulling technique was used to grow the crystal the same way as in Example 1. A full size perfect single crystal of LSO was produced. The crystal was then cut into slices for evaluation. The light yield and decay time of the first and last slice cut out of the crystal after the thermal annealing process was measured. The following were the measured values.

The bottom slice of the annealed crystal had a light yield of 6.56×BGO reference, and a decay time of 32.94 ns, with an R value of 5.02. The top slice of the fully annealed sample had a light yield of 7.18×BGO reference, and a decay time of 33.52 ns, with an R value of 4.67.

Comparing this result to the LYSO crystal in Example 3 with the same amount of calcium, magnesium and cerium co-doping, the light yield of the LSO crystal was only slightly lower, but still very respectable. It was surprising that the decay time did not reduce as much, but still stayed in the 33 ns range. As a result, the R value was also slightly higher than that of the LYSO crystal. Nevertheless, this calcium and magnesium co-doped LSO still showed high light yield, short decay time and thus very low R value as compared to the result of the Andreaco '419 Example 3 with calcium co-doped with cerium.

H. Example 8. The decay time result of Example 7 was surprising. It appeared that calcium doping was less effective to reduce the decay time in the LSO crystal as compared to that in the LYSO crystal. Based on the result of Example 6, it was decided to start a new growth run with 0.50% calcium co-doped with 0.05% magnesium and 0.05% cerium in a LSO crystal. The same standard Czochralski melt pulling technique was used to grow the crystal the same way as in Example 1. It was positive that a full size crystal was obtained without fracture after growth. The crystal was then cut into slices for evaluation. The light yield and decay time of the first and last slice cut out of the crystal after the thermal annealing process was measured. The following were the measured values.

The bottom slice of the annealed crystal had a light yield of 5.26×BGO reference, and a decay time of 25.90 ns, with an R value of 4.92. The top slice of the annealed sample had a light yield of 5.83×BGO reference, and a decay time of 28.67 ns, with an R value of 4.92.

The result was very comparable to that of the LYSO crystal with similar doping composition. It showed that higher Ca-doping will work equally well in the LSO crystal. Similar to that of LYSO crystal, the quantum efficiency was decreased and the light yield was also reduced as a result. It was observed that the decay time can be further reduced down to even 26 ns and still retain a decent light yield. The R value increased only very slightly, but still remained below the desired 5.0.

Any LSO crystals with Ca2+ doping concentration from 0.05% up to 0.50% and co-doped with magnesium and cerium can expect excellent performance to be used as PET detectors. This excellent performance can be achieved with co-doping of magnesium in a controlled amount. The actual choice of the doping composition will also depend on the design and the requirement of the ToF PET scanner. Even this high calcium doped LSO survived without fracture after growth. Higher calcium doping will stress the crystal and make it face a higher risk of fracture.

For comparison, Spurrier et. al. disclosed in 2007 a LSO crystal doped with 0.4% calcium and 0.1% cerium without magnesium co-doping. It had a light yield of 34,800 Photons/MeV or 4.46×BGO and a decay time of 31 ns. The R value was 6.95.

I. Example 9. The examples above completed the investigation of Mg2+ and Ca2+, co-doped with Ce3+ in LYSO and LSO crystals. In order to complete the investigation, it was possible to make a further study to see the effect of the same pair substitutions in a LGSO crystal host.

In order to be able to obtain the direct comparison, the doping composition of the LGSO crystal was set substantially the same as Example 3 and Example 7 at 0.05% magnesium and 0.09% calcium with 0.05% cerium in this LGSO crystal. The composition of the LGSO crystal itself was set at 5% of the gadolinium and 95% of the lutetium. The same standard Czochralski melt pulling technique was used to grow the crystal the same way as in Example 1. A full size perfect single LGSO crystal was produced without fracture. The crystal was then cut into slices for evaluation. The light yield and decay time of the first and last slice cut out of the crystal after the thermal annealing process was measured. The following were the measured values.

The bottom slice of the annealed crystal had a light yield of 6.24×BGO reference, and a decay time of 31.93 ns, with an R value of 5.12. The top slice of the fully annealed sample had a light yield of 6.60×BGO reference, and a decay time 31.72 ns, with an R value of 4.81.

Comparing with the light yield and decay time result of both LYSO and LSO, the light yield of the LGSO crystal was distinctly lower. The scintillating performance of the LGSO crystal was the least desirable among the three host crystals with a slightly higher R value.

In these example embodiments, it was determined that the co-doping of calcium and magnesium with cerium in the Titanite structures of LSO, LYSO and LGSO crystals can enhance significantly their scintillating performance. A new parameter was introduced as the R value as defined above, and found that it was an ideal value to be able to make the direct comparison of performance among all the known scintillator materials. For example, the base material bismuth germanium oxide (BGO) crystal will have a Rn value of 300. NaI(Tl) has a value of 50. Ce-doped Gadolinium Aluminum Gallium Garnet (Ce) (GAGG) has a value of 10.4. Currently, both calcium and cerium co-doped LSO and CPI calcium and cerium co-doped LYSO in accordance with the '419 patent have an R value of 6.4. They both are currently used in all the high end ToF PET scanners. Spurrier's disclosure of high, i.e., 0.4 at % calcium and coped LSO only has an R value of 6.95.

It was demonstrated that the crystals in the above examples showed a much lower R value as compared to other known scintillator crystals, except cerium doped LaBr₃. This indicates that when comparing the current commercial PET detectors, the crystals illustrated in these examples are better materials for ToF PET applications. It has been determined that crystals with an R value less than 5.0 should be considered as a good scintillator materials for the top end ToF PET application.

Through extensive experimentation and testing, it has been determined that the function of calcium doping is substantially different from that of magnesium doping when they both are co-doped in the example Titanite structural crystal hosts. They do not occupy the same structural site. Ca2+ is primarily occupied in the A(7) site, and Mg2+ is primarily occupied in the B(6) site. Mg2+ will occupy the A(7) site only if it is doped alone without Ca2+, or when doping in excess with Ca2+.

It has also been determined that LSO, LYSO and LGSO materials have the charge neutrality issue due to the loss of the non-silicon bonding oxygen in the A(7) site of the crystal structure during crystal growth at high temperatures with low ambient oxygen partial pressure. Before the discovery of the post growth thermal oxygen annealing process, calcium doping had been used effectively to neutralize the charge imbalance and to reduce the problem of afterglow. Currently, this post growth thermal oxygen annealing process is used by virtually all scintillator crystal producers to back fill and eliminate the oxygen vacancy defects. Calcium doping is no longer required for charge neutralization. Calcium doping may prevent the refill of these oxygen vacancies and will leave a permanent structural defect within these crystals.

Nevertheless, this may be desirable to achieve. In the examples as described, Ca2+ is doped not only for the purpose of charge neutralization of the missing oxygen, but also to create a permanent structural defect and increase the crystal lattice distortion of the A(7) site that can induce the faster decay of the Ce3+ emission in that site. Calcium induced distortion is most effective if the defect occurs in the neighborhood of the emitting Ce3+ ion. The Ca2+ ion will be attracted by the negative charge and locate to wherever there is a missing oxygen. The ion does not have any preference to be closer to Ce3+ ion. Since the total doping amount of Ce3+ is limited, higher Ca2+ doping will increase the chance to be in close neighborhood to a Ce3+ ion. The lattice distortion near the Ce3+ emission site will not only increase the decay rate, but also reduce the scintillating light yield.

The introduced R value appears to be the best parameter to make direct comparison of the scintillating performance of different hosts. The experimental data shows that with increasing calcium doping from 0.05% to 0.50%, the R value will stay nearly the same only if the crystal is also co-doped with magnesium. The experimental data suggests that it is possible to maintain the R value at near the minimum, and at the same time reduce the decay constant down to 26 ns.

The Mg2+ doping, on the other hand, has a substantially different function. Mg2+ ion will occupy only in the B(6) site. It is a true charge compensator to maintain the cerium ions occupied in the B(6) site to stay in 4+ charge state. Because of the charge neutrality, there is a clear preference for magnesium to stay close to the cerium ion. In this way, the cerium ions in the B(6) sites will stay in 4+ state and become a non-emitter, and not interfere with the scintillating emission of the Ce3+ ion in the A(7) site. Without the Mg2+ doping, Ca2+ in the A(7) site that is in close neighbor to the cerium in the B(6) site can act as charge compensator to keep cerium in the 4+ state, which is ineffective. It is also not possible to achieve 100% elimination of the Ce3+ ion in the B(6) site with Mg2+ doping alone, without the Ca2+ co-doping, since most of the Mg2+ will occupy in the A(7) site and be attracted by the negative charge due to the missing oxygen.

The Ca2+ and Ce3+ co-doped LSO, LYSO and LGSO are currently the choice of scintillating detectors for the high end ToF PET scanners. Today, calcium, cerium currently produced co-doped LYSO crystal can achieve a light yield of 45,000 photons/MeV and 40 ns of decay time and have an R value of 6.40.

In the experimental examples described above, it was demonstrated that it is possible to enhance further the scintillating performance of these Titanite structural crystals. It was demonstrated that doping of Ca2+ and Mg2+ with proper concentration with Ce3+ can improve the scintillating performance of LSO, LYSO and LGSO beyond the level of current available materials and obtain a low R value below 5.0. This improvement has ascended these crystals to a new high performance level, and will be the best quality detectors for the next generation of high-end ToF-PET scanners. They can also be used as imaging sensors in other medical applications, and also calorimetric detectors in high energy physics for years in the future.

In these improved LSO, LYSO and LGSO crystal structures, it is possible to add small amounts of cations other than the magnesium, calcium, and cerium described above because their ionic size and charge allow them to fit into the structure. Possible cations that may be added include:
For 3+ charge cations—La, Sc, Pr, Tb;
   For 2+ charge cations—Sr, Zn, Cd

There are also other elements in the periodic table that can be added to the melt. Depending on different aspects, they may or may not be able to incorporate into the crystal structure. The amount of doping of these cations will be usually traces and should not exceed 10% of the lutetium, yttrium and gadolinium combined.

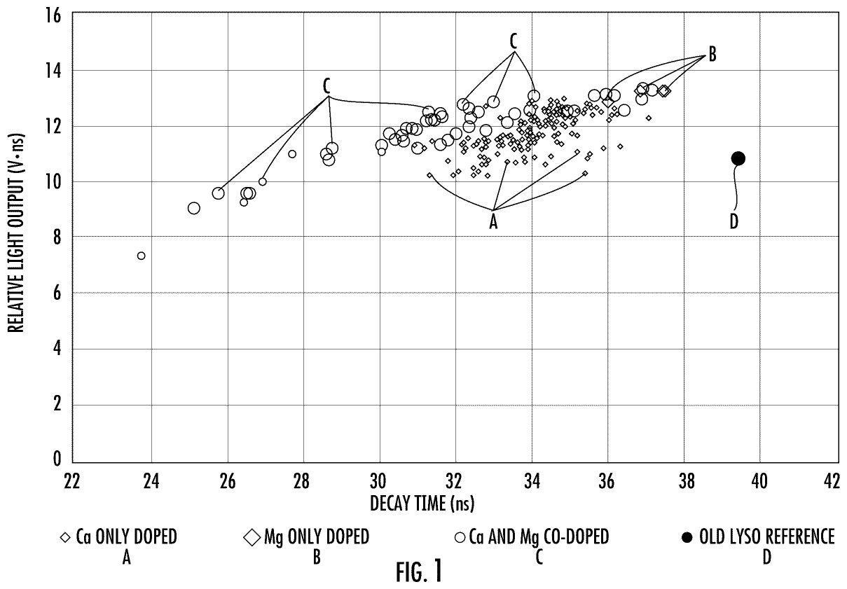

Extensive experimentation and testing has been accomplished for LYSO scintillator crystals comparing 1) older commercial versions of LYSO scintillator crystals, and scintillator crystals that have 2) calcium only doping, 3) magnesium only doping and the 4) new calcium and magnesium co-doping. The results for this extensive experimentation and testing are shown in the graph of FIG. 1, where the four different scintillator crystal performances are illustrated. The relative light output is shown on the vertical axis and the decay time on the horizontal axis. These results show that the improved LYSO scintillator crystal with magnesium and calcium co-doping together in the ranges and amounts as described obtains the best R value having the fast decay time and excellent relative light output. Based upon the discussions above and further experimentation and testing, similar results and ranges for calcium, magnesium and cerium will apply to LSO and LGSO scintillator crystals.

An example LYSO scintillator crystal is formed as a monocrystalline structure of cerium, calcium and magnesium doped lutetium yttrium orthosilicate (LYSO), Ce₂ₓ Ca_{2y} Mg_{2z} (Luₚ Y_{q})_{2(1-x-y-z}) SiO₅. In a non-limiting example, x is between 0.0003 to 0.001, y is between 0.0005 to 0.003, and z is between 0.0003 to 0.001. The monocrystalline structure has an R value less than 5 corresponding to the decay time in nanoseconds divided by the light yield with respect to a Bismuth Germanium Oxide (BGO) reference. Although a specific range is set forth and determined optimal through the numerous experiments such as shown in the graph of FIG. 1, the values in these ranges can vary depending on the scintillator crystal requirements, by as much as about 5% to about 10% above and below these indicated ranges.

The extensive experimentation as evident in the graph of FIG. 1 has aided in defining the ranges as described for the LYSO scintillator crystal, which also apply for the LSO and LGSO scintillator crystals. An optimum value has been determined for the cerium, calcium and magnesium. For an example LYSO scintillator crystal, x may be about 0.0005. Y may be about 0.0009. Z may be about 0.0005. For the ranges of Lutetium and Yttrium, P may be between 0.01 to 0.99 and q may be between 0.01 and 0.99. For an optimum value, p may be about 0.90 and q may be about 0.10.

The monocrystalline structure for this LYSO scintillator crystal may have a scintillating light yield greater than 6.5 BGO (or 50,000 Ph/MeV) and a decay time less than 32 nanoseconds under 511 Kev radiation. The monocrystalline structure may include at least one additional 2+ charge cation dopant, such as one or more of strontium (Sr), zinc (Zn) and cadmium (Cd). The monocrystalline structure may also include at least one additional 3+ charge cation dopant, such as one or more of Lanthanum (La), Scandium (Sc), Praseodymium (Pr) and Terbium (Tb).

In another example, the LYSO scintillator crystal may include a monocrystalline structure of cerium, calcium and magnesium doped lutetium yttrium orthosilicate (LYSO) wherein the cerium is about 0.03 at % to about 0.1 at %, the calcium is about 0.05 at % to about 0.3 at %, and the magnesium is about 0.03 at % to about 0.1 at %. As noted above, these values may range up to about 5% to about 10% above and below the stated values in the range. The monocrystalline structure may have an R value less than 5 corresponding to the decay time in nanoseconds divided by the light yield with respect to a Bismuth Germanium Oxide (BGO) reference.

The optimum amount of the cerium, calcium and magnesium may vary depending on end-use. In a non-limiting example, the cerium may be about 0.05 at %. The calcium may be about 0.09 at %. The magnesium may be about 0.05 at %. The Lutetium may be about 1 at % to about 99 at %, and the Yttrium may be about 1 at % to about 99 at %. In an example LYSO scintillator crystal, the Lutetium may be about 90 at % and the Yttrium may be about 10 at %.

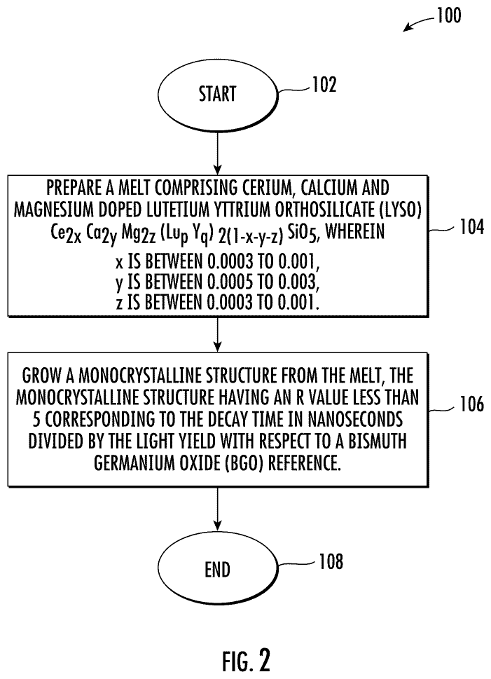

Referring now to FIG. 2, there is illustrated generally at 100 a high-level flowchart of method of making a scintillator crystal from a melt. The process starts (Block 102) and includes preparing a melt having cerium, calcium and magnesium doped lutetium yttrium orthosilicate (LYSO), Ce₂ₓ Ca_{2y} Mg_{2z} (Luₚ Y_{q})_{2(1-x-y-z)} SiO₅, where x is between 0.0003 to 0.001, y is between 0.0005 to 0.003, and z is between 0.0003 to 0.001 (Block 104). The method includes growing a monocrystalline structure from the melt, the monocrystalline structure having an R value less than 5 corresponding to the decay time in nanoseconds divided by the light yield with respect to a Bismuth Germanium Oxide (BGO) reference (Block 106). The process ends (Block 108).

In an example LGSO crystal, the scintillator crystal may include a monocrystalline structure of cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅. The range of values may be similar as described for the LYSO crystal above, where x is between 0.0003 to 0.001, y is between 0.0005 to 0.003, and z is between 0.0003 to 0.001. As with the LYSO crystal, the ranges may vary from about 5% to about 10% above and below these values. The LGSO monocrystalline structure may have an R value less than 5 corresponding to the decay time in nanoseconds divided by the light yield with respect to a Bismuth Germanium Oxide (BGO) reference.

In a non-limiting example of an optimum value, x may be about 0.0005, y may be about 0.0009 and z may be about 0.0005. P may be between 0.01 to 0.99 and r may be between 0.01 and 0.99. P may be about 0.95 and r may be about 0.05. The monocrystalline structure for the LGSO crystal may have a scintillating light yield greater than 6.5 BGO (or 50,000 Ph/MeV) and a decay time less than 32 nanoseconds under 511 Kev radiation.

The monocrystalline structure for this example LGSO crystal may include at least one additional 2+ charge cation dopant, such as one or more of strontium (Sr), zinc (Zn) and cadmium (Cd). The monocrystalline structure may also include at least one additional 3+ charge cation dopant, such as one or more of Lanthanum (La), Scandium (Sc), Praseodymium (Pr) and Terbium (Tb).

In another non-limiting example, the LGSO scintillator crystal may include a monocrystalline structure of cerium, calcium and magnesium doped lutetium gadolinium orthosilicate (LGSO) wherein the cerium is about 0.03 at % to about 0.1 at %, the calcium is about 0.05 at % to about 0.3 at %, and the magnesium is about 0.03 at % to about 0.1 at %. The monocrystalline structure may have an R value less than 5 corresponding to the decay time in nanoseconds divided by the light yield with respect to a Bismuth Germanium Oxide (BGO) reference.

The cerium may be about 0.05 at %, the calcium may be about 0.09 at % and the magnesium may be about 0.05 at %. The Lutetium may be about 1 at % to about 99 at %, and the Gadolinium may be about 1 at % to about 99 at %. The Lutetium may be about 95 at % and the Gadolinium may be about 5 at %.

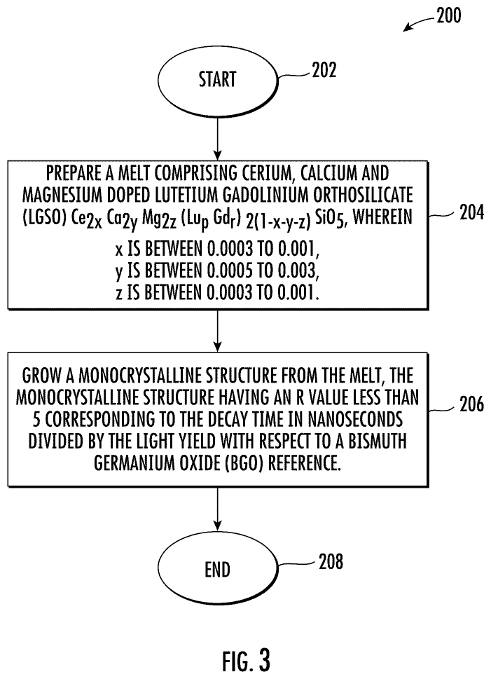

Referring now to FIG. 3, a method of making a scintillator crystal from a melt is shown generally at 200. The method starts (Block 202) and includes preparing a melt comprising cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅, where x is between 0.0003 to 0.001, y is between 0.0005 to 0.003, and z is between 0.0003 to 0.001 (Block 204). The method includes growing a monocrystalline structure from the melt, the monocrystalline structure having an R value less than 5 corresponding to the decay time in nanoseconds divided by the light yield with respect to a Bismuth Germanium Oxide (BGO) reference (Block 206). The process ends (Block 208).

The experiments and tests have also confirmed positive results for the LSO scintillator crystal, which may include a monocrystalline structure of cerium, calcium and magnesium doped lutetium orthosilicate (LSO), Ce₂ₓ Ca_{2y} Mg_{2z} Lu_{2(1-x-y-z)} SiO₅, where x is between 0.0003 to 0.001, y is between 0.0005 to 0.003, and z is between 0.0003 to 0.001. The monocrystalline structure may have an R value less than 5 corresponding to the decay time in nanoseconds divided by the light yield with respect to a Bismuth Germanium Oxide (BGO) reference.

Similar to the LSYO and LGSO crystals, in the example LSO crystal, x may be about 0.0005, y may be about 0.0009, and z may be about 0.0005. The monocrystalline structure may have a scintillating light yield greater than 6.5 BGO (or 50,000 Ph/MeV) and a decay time less than 32 nanoseconds under 511 Kev radiation.

The LSO monocrystalline structure may also include at least one additional 2+ charge cation dopant, such as one or more of strontium (Sr), zinc (Zn) and cadmium (Cd). The LSO monocrystalline structure may also include at least one additional 3+ charge cation dopant, such as one or more of Lanthanum (La), Scandium (Sc), Praseodymium (Pr) and Terbium (Tb).

In another example, the LSO scintillator crystal may include a monocrystalline structure of cerium, calcium and magnesium doped lutetium orthosilicate (LSO) wherein the cerium is about 0.03 at % to about 0.1 at %. The calcium is about 0.05 at % to about 0.3 at %. The magnesium is about 0.03 at % to about 0.1 at %. The monocrystalline structure may have an R value less than 5 corresponding to the decay time in nanoseconds divided by the light yield with respect to a Bismuth Germanium Oxide (BGO) reference. The cerium may be about 0.05 at %, the calcium may be about 0.09 at % and the magnesium may be about 0.05 at %.

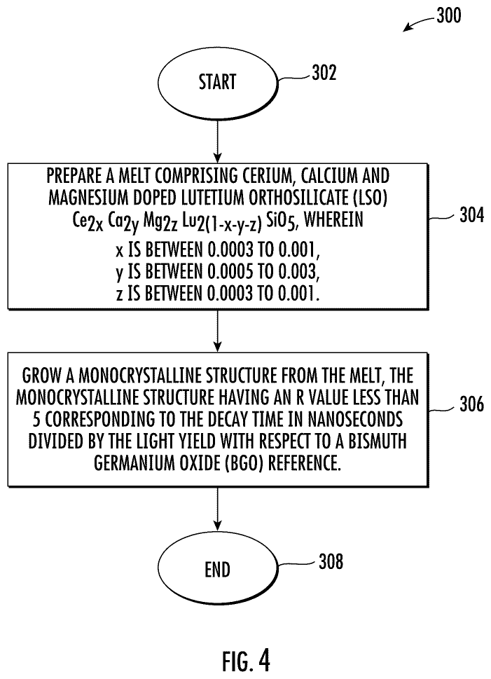

Referring now to FIG. 4, a high-level flowchart is illustrated generally at 300 for a method of making the LSO a scintillator crystal. The process starts (Block 302) by preparing a melt that includes cerium, calcium and magnesium doped lutetium orthosilicate (LSO), Ce₂ₓ Ca_{2y} Mg_{2z} Lu_{2(1-x-y-z)} SiO₅, where x is between 0.0003 to 0.001, y is between 0.0005 to 0.003, and z is between 0.0003 to 0.001 (Block 304). The method includes growing a monocrystalline structure from the melt, the monocrystalline structure having an R value less than 5 corresponding to the decay time in nanoseconds divided by the light yield with respect to a Bismuth Germanium Oxide (BGO) reference (Block 306).

This application is related to copending patent applications entitled, “SCINTILLATOR CRYSTAL HAVING CERIUM, CALCIUM, AND MAGNESIUM DOPED LSO AND ASSOCIATED METHODS,” and “SCINTILLATOR CRYSTAL HAVING CERIUM, CALCIUM, AND MAGNESIUM DOPED LYSO AND ASSOCIATED METHODS,” which are filed on the same date and by the same assignee and inventors, the disclosures which are hereby incorporated by reference.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A scintillator crystal, comprising:
a monocrystalline structure of cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅, wherein
x is between 0.0003 to 0.001;
y is between 0.0005 to 0.003;
z is between 0.0003 to 0.001; and
the monocrystalline structure has an R value less than 5 corresponding to the decay time in nanoseconds divided by the light yield with respect to a Bismuth Germanium Oxide (BGO) reference.

2. The scintillator crystal of claim 1 wherein x is about 0.0005.

3. The scintillator crystal of claim 2 wherein y is about 0.0009.

4. The scintillator crystal of claim 1 wherein z is about 0.0005.

5. The scintillator crystal of claim 1 wherein p is between 0.01 to 0.99 and r is between 0.01 and 0.99.

6. The scintillator crystal of claim 5 wherein p is about 0.95.

7. The scintillator crystal of claim 5 wherein r is about 0.05.

8. The scintillator crystal of claim 1 wherein the monocrystalline structure has a scintillating light yield greater than 6.5 BGO and a decay time less than 32 nanoseconds under 511 Kev radiation.

9. The scintillator crystal of claim 1 wherein the monocrystalline structure further comprises at least one additional 2+ charge cation dopant.

10. The scintillator crystal of claim 9 wherein the at least one 2+ charge cation dopant comprises one or more of strontium (Sr), zinc (Zn) and cadmium (Cd).

11. The scintillator crystal of claim 1 wherein the monocrystalline structure further comprises at least one additional 3+ charge cation dopant.

12. The scintillator crystal of claim 11 wherein the at least one 3+ charge cation comprises one or more of Lanthanum (La), Scandium (Sc), Praseodymium (Pr) and Terbium (Tb).

13. A scintillator crystal, comprising:
a monocrystalline structure of cerium, calcium and magnesium doped lutetium gadolinium orthosilicate (LGSO) wherein
cerium is about 0.03 at % to about 0.1 at %;
calcium is about 0.05 at % to about 0.3 at %; and
magnesium is about 0.03 at % to about 0.1 at %.

14. The scintillator crystal of claim 13 wherein the monocrystalline structure has an R value less than 5 corresponding to the decay time in nanoseconds divided by the light yield with respect to a Bismuth Germanium Oxide (BGO) reference.

15. The scintillator crystal of claim 13 wherein the cerium is about 0.05 at %.

16. The scintillator crystal of claim 13 wherein the calcium is about 0.09 at %.

17. The scintillator crystal of claim 13 wherein the magnesium is about 0.05 at %.

18. The scintillator crystal of claim 13 wherein the Lutetium is about 1 at % to about 99 at %, and the Gadolinium is about 1 at % to about 99 at %.

19. The scintillator crystal of claim 18 wherein the Lutetium is about 95 at %.

20. The scintillator crystal of claim 18 wherein the Gadolinium is about 5 at %.

21. The scintillator crystal of claim 13 wherein the monocrystalline structure has a scintillating light yield greater than 6.5 BGO and a decay time less than 32 nanoseconds under 511 Kev radiation.

22. The scintillator crystal of claim 13 wherein the monocrystalline structure further comprises at least one additional 2+ charge cation dopant.

23. The scintillator crystal of claim 22 wherein the at least one 2+ charge cation dopant comprises one or more of strontium (Sr), zinc (Zn) and cadmium (Cd).

24. The scintillator crystal of claim 13 wherein the monocrystalline structure further comprises at least one additional 3+ charge cation dopant.

25. The scintillator crystal of claim 24 wherein the at least one 3+ charge cation comprises one or more of Lanthanum (La), Scandium (Sc), Praseodymium (Pr) and Terbium (Tb).

26. A method of making a scintillator crystal from a melt comprising:
preparing a melt comprising cerium, calcium and magnesium doped lutetium gadolinium orthosilicate (LGSO), Ce₂ₓ Ca_{2y} Mg_{2z} (Luₚ Gdᵣ)_{2(1-x-y-z)} SiO₅, wherein
x is between 0.0003 to 0.001;
y is between 0.0005 to 0.003;
z is between 0.0003 to 0.001; and
growing a monocrystalline structure from the melt, the monocrystalline structure having an R value less than 5 corresponding to the decay time in nanoseconds divided by the light yield with respect to a Bismuth Germanium Oxide (BGO) reference.

27. The method of claim 26 wherein x is about 0.0005.

28. The method of claim 26 wherein y is about 0.0009.

29. The method of claim 26 wherein z is about 0.0005.

30. The method of claim 26 wherein p is between 0.01 to 0.99 and r is between 0.01 and 0.99.

31. The method of claim 30 wherein p is about 0.95.

32. The method of claim 30 wherein r is about 0.05.

33. The method of claim 26 wherein the monocrystalline structure has a scintillating light yield greater than 6.5 BGO and a decay time less than 32 nanoseconds under 511 Kev radiation.

34. The method of claim 26 comprising adding at least one additional 2+ charge cation dopant to the melt.

35. The method of claim 34 wherein the at least one 2+ charge cation dopant comprises one or more of strontium (Sr), zinc (Zn) and cadmium (Cd).

36. The method of claim 26 comprising adding at least one additional 3+ charge cation dopant to the melt.

37. The method of claim 36 wherein the at least one 3+ charge cation comprises one or more of Lanthanum (La), Scandium (Sc), Praseodymium (Pr) and Terbium (Tb).
